(19) United States
(12) Patent Application Publication
(10) Pub. No.: US 2019/0189855 A1
(43) Pub. Date: Jun. 20, 2019

(54) OPTOELECTRONIC DEVICE AND PROCESS OF PRODUCING AN OPTOELECTRONIC DEVICE

(71) Applicant: OSRAM Opto Semiconductors GmbH, Regensburg (DE)

(72) Inventors: Thomas Reeswinkel, Regensburg (DE); Tobias Gebuhr, Regensburg (DE); Artöm Khassanov, Erlangen (DE)

(21) Appl. No.: 16/221,872

(22) Filed: Dec. 17, 2018

(30) Foreign Application Priority Data
Dec. 19, 2017 (DE) 10 2017 130 528.9

(51) Int. Cl. H01L 33/44; H01L 33/50; H01L 33/52; H01L 21/02; G03F 7/16; G02B 6/42

(52) U.S. Cl. CPC H01L 33/44; H01L 33/504; G02B 6/4239; H01L 21/02126; G03F 7/165; H01L 33/52

(57) ABSTRACT

An optoelectronic device includes an active layer stack that generates or detects radiation, a radiation entrance or radiation exit surface including an inorganic material, and a protective layer disposed over the radiation entrance or radiation exit surface and including chemical compounds each containing an anchor group and a head group, wherein the anchor group is bonded to the inorganic material, and an encapsulation laterally surrounding at least the active layer stack or at least the active layer stack and the protective layer.

### TECHNICAL FIELD

This disclosure relates an optoelectronic device and a process of producing an optoelectronic device.

### BACKGROUND

Optoelectronic devices such as light-emitting diodes, laser diodes or light detectors are frequently encapsulated with an encapsulation material laterally by injection molding. In that process, undesirable residues of the encapsulation material can be deposited at the radiation entrance or radiation exit surface, which impair the optical properties of the optoelectronic device.

Conventionally, the resulting residues on the radiation entrance or radiation exit surface are removed by an ablation process, for example, wet blasting, electrochemical deflashing or plasma-made flashing. However, those ablation processes are associated with a high effort and can damage the radiation entrance or radiation exit surface.

It could be helpful to provide an optoelectronic device with an improved radiation entrance or radiation exit surface and a process of producing an optoelectronic device.

### SUMMARY

We provide an optoelectronic device including an active layer stack that generates or detects radiation, a radiation entrance or radiation exit surface comprising an inorganic material, and a protective layer disposed over the radiation entrance or radiation exit surface and comprising chemical compounds each containing an anchor group and a head group, wherein the anchor group is bonded to the inorganic material, and an encapsulation laterally surrounding at least the active layer stack or at least the active layer stack and the protective layer.

We also provide a process of producing the optoelectronic device including an active layer stack that generates or detects radiation, a radiation entrance or radiation exit surface comprising an inorganic material, and a protective layer disposed over the radiation entrance or radiation exit surface and comprising chemical compounds each containing an anchor group and a head group, wherein the anchor group is bonded to the inorganic material, and an encapsulation laterally surrounding at least the active layer stack or at least the active layer stack and the protective layer including A) providing the active layer stack that generates or detects radiation on the substrate, B) applying the chemical compounds, each containing an anchor group and a head group, to the surface of the optoelectronic device provided as a radiation entrance or radiation exit surface, the surface including the inorganic material, C) reacting the anchor group of the chemical compounds with the inorganic material of the radiation entrance or radiation exit surface to form the protective layer, and D) arranging the encapsulation material to form the encapsulation laterally surrounding at least the active layer stack or at least the active layer stack and the protective layer.

We further provide an optoelectronic device including an active layer stack that generates or detects radiation, a radiation entrance or radiation exit surface comprising an inorganic material, a protective layer disposed over the radiation entrance or radiation exit surface and comprising chemical compounds each containing an anchor group and a head group, wherein the anchor group is bonded to the inorganic material, and an encapsulation laterally surrounds at least the active layer stack or the at least the active layer stack and the protective layer, wherein the inorganic material is at least one selected from the group consisting of an oxide, a nitride, an oxynitride, a carbide, a carbonitride, a fluoride and a silicate without silicone.

### BRIEF DESCRIPTION OF THE DRAWINGS

FIGS. 1A and 1B show schematic side view of an example of an optoelectronic device.

FIGS. 2A to 2H show a process of producing an example of an optoelectronic device.

FIG. 3A shows formation of a protective layer on a radiation entrance or radiation exit surface.

FIG. 3B shows examples of chemical compounds for a protective layer.

FIG. 4 shows a film assisted molding process.

### LIST OF REFERENCE NUMERALS

100 optoelectronic device
1 substrate
2 active layer stack
3 radiation entrance or radiation exit area
4 protective layer
4a surface of the protective layer
5 optical element
7 conversion element
6 encapsulation
8 metallization
9 bonding wire
10 adhesive layer
11 first mold
12 second mold
13 separating foil
14 encapsulation material
A anchor group
K head group
M middle group

### DETAILED DESCRIPTION

Our optoelectronic device comprises an active layer stack that generates or detects radiation.

The device may comprise a radiation entrance or radiation exit surface. In particular, electromagnetic radiation from the surroundings can be coupled into the device via the radiation entrance surface, and electromagnetic radiation, generated in particular by the active layer stack, can be radiated from the device into the surroundings via the radiation exit surface. The radiation entrance or radiation exit surface may be a main surface of the active layer stack or a main surface of an optical element located above the active layer stack.

The fact that a layer or element is arranged or applied “on” or “above” another layer or element may mean that one layer or element is arranged or applied directly in mechanical and/or electrical contact with the other layer or element. Furthermore, it can also mean that one layer or element is arranged indirectly on or above the other layer or element. Further layers and/or elements can then be arranged between one or the other layer or between one or the other element.

The radiation entrance or radiation exit surface may comprise an inorganic material or is formed with an inorganic material. It is preferred that the optical element or the active layer stack, which has the radiation entrance or radiation exit surface, is also made of the inorganic material or comprises the inorganic material.

An inorganic material is a material that does not contain any organic compounds. Organic compounds are in particular compounds containing carbon in combination with hydrogen or carbon-carbon bonds, in particular compounds derived from methane, the group of alkane or hydrocarbons. In particular, silicones, i.e., polysiloxanes, do not fall under the definition of the inorganic material described here. It is possible that the inorganic material may contain organic compounds and/or siloxanes in the form of impurities, these impurities taken together preferably not exceeding 1 per mille or 100 ppm (parts per million) or 10 ppm by weight.

A protective layer comprising chemical compounds, each containing an anchor group and a head group, au be arranged above the radiation entrance or radiation exit surface. The chemical compound may also consist of the anchor group and the head group. The anchor group is particularly bound to the head group by a covalent bond. The anchor group is bound to the inorganic material of the radiation entrance or radiation exit surface. Preferably, the protective layer is therefore in direct mechanical contact with the radiation entrance or radiation exit surface.

In conventional devices, the radiation entrance or radiation exit surface forms the interface between the device and the surroundings. However, we found that radiation entrance or radiation exit surfaces formed from an inorganic material have a high affinity for the deposition and/or adhesion of encapsulation material, which in some instances can only be removed with great effort. Such deposits of the encapsulation material impair the optical properties of the device such as the brightness or radiation characteristics of radiation-emitting optoelectronic devices such as light-emitting diodes or laser diodes.

We found out that the wettability with and/or adhesion of encapsulation material is considerably reduced by the protective layer. Chemical compounds having an anchor group and a head group have proven to be particularly suitable for this purpose for the protective layer, the head group having properties enabling a reduction in adhesion, deposition and/or wettability. By the anchor groups of the chemical compounds, these can be bound to the inorganic material at the radiation exit or entrance surface. An adhesive layer that adheres the protective layer to the radiation exit or entrance surface can therefore advantageously be dispensed with. The anchor group is thus bound to the inorganic material at the radiation exit or entrance surface, while the head group is directed outwards, for example, away from the radiation exit or entrance surface. In particular, the head groups of the chemical compounds are located on the surface of the protective layer facing away from the entrance or exit surface of the radiation.

That “the anchor group is bound to the inorganic material at the radiation exit or entrance surface” means that the anchor groups of the chemical compounds are bound to the inorganic material located at the interface of the radiation exit or entrance surface to the protective layer. In particular, the chemical compounds are not bound to the inorganic material below this interface.

The protective layer may have a surface facing away from the radiation entrance or radiation exit surface, which is arranged parallel to the radiation entrance or radiation exit surface. This surface of the protective layer forms in particular an interface with the surroundings.

The inorganic material may comprise an oxide, a nitride, a carbide, a carbonitride, a fluoride, an oxynitride or a silicate or consists of an oxide, a nitride, a carbide, a carbonitride, a fluoride or a silicate or combinations thereof. In particular, the inorganic material comprises a metal oxide, a metal oxynitride, a metal nitride, a metal carbide, a metal carbonitride, metal fluoride or a silicate or consists of a metal oxide, a metal oxynitride, a metal nitride, a metal carbide, a metal carbonitride or a silicate. The metal oxide can be aluminium oxide and/or silicon oxide, for example. The metal nitride can be aluminium nitride and/or silicon nitride.

The inorganic material may be, in particular, the metal nitride, metal oxide, a glass, a ceramic or sapphire. The metal oxide, the glass or the ceramic comprises or preferably consists of silicon oxide. In particular, these materials have a certain hardness necessary to not damage this material during subsequent production processes such as an injection molding process, in particular a film assisted molding process to encapsulate the active layer stack or the active layer stack and the protective layer with an encapsulation. The hardness is also particularly necessary to achieve a form-fitting seal in film assisted molding or to be able to seal up to the edges of the radiation entrance or radiation exit surface so that as little encapsulation material as possible is deposited on the surface.

The protective layer may be a low-molecular layer consisting of chemical compounds containing an anchor group and a head group. A low-molecular layer is an arrangement of a few monolayers of the chemical compound that lie on top of each other in a vertical direction of view. For example, two to 20 or two to ten monolayers of the chemical compound are arranged one above the other.

The protective layer may be a monomolecular layer consisting of chemical compounds each containing an anchor group and a head group. In other words, the chemical compounds bound with the anchor group to the inorganic material, preferably the metal oxide of the radiation exit or entrance surface, form a monomolecular layer. Thus, in the vertical direction of view, there is no arrangement of several chemical compounds, lying one on top of the other, on the radiation exit or entrance surface.

In this way, particularly thin layer thicknesses of the protective layer are possible. For example, the layer thickness of the protective layer may be less than 100 nm, in particular less than 50 nm, preferably less than 10 nm, more preferably less than 5 nm and especially preferred less than 3 nm. Even with these thin layer thicknesses, adhesion of materials and/or wettability with encapsulation material can be significantly reduced. Alternatively or additionally, the layer thickness of the protective layer can be greater than or equal to 0.5 nm.

Due to formation of the protective layer as a thin monomolecular layer, the chemical compounds do not or only slightly impair the appearance and optical properties of the radiation exit or entrance surface. In other words, the radiation can also be efficiently coupled in or out with the protective layer.

The chemical compounds bound to the inorganic material, in particular to the metal oxide, with the anchor group may form a self-assembling monolayer (SAM). SAMs are particularly advantageous because they have a high degree of order and thus enable a compact arrangement of the chemical compounds at the radiation exit or entrance surface, which further reduces the adhesion and wetting conditions.

The head group may be selected from a group comprising linear alkyl groups, branched alkyl groups, at least partially fluorinated linear alkyl groups, at least partially fluorinated branched alkyl groups, perfluorinated linear alkyl groups and perfluorinated branched alkyl groups.

With linear alkyl groups, at least partially fluorinated linear alkyl groups or perfluorinated linear alkyl groups, the chemical compounds can be arranged particularly compactly at the radiation entrance or radiation exit surface. The more compact the arrangement of the chemical compounds, the more clearly adhesion to an encapsulating material can be reduced. Even compact SAMs can be produced particularly well with linear alkyl groups, at least partially fluorinated linear alkyl groups or perfluorinated linear alkyl groups.

Partially fluorinated and perfluorinated head groups lead to a particularly significant reduction in the tendency to adhere to encapsulation material coming into contact with the head groups. In addition, fluorinated groups have the effect of reducing the coefficient of friction. Coefficients of friction are a measure of sliding friction and, in particular, static friction and thus also reflect static and adhesive properties. If the coefficient of friction is reduced, the adhesion of the surface is also reduced.

Branched alkyl groups, at least partially fluorinated branched alkyl groups or perfluorinated branched alkyl groups as head groups also reduce adhesion, wherein the high steric demand of the branched alkyl groups, at least partially fluorinated branched alkyl groups or perfluorinated branched alkyl groups can be exploited to cover or shield a wide area of the radiation entrance or radiation exit surface. Thus, fewer chemical compounds may be necessary to reduce adhesion if branched (fluorinated) alkyl groups are present as the head group than with linear (fluorinated) alkyl groups as the head group.

Alkyl groups, at least partially fluorinated alkyl groups or perfluorinated alkyl groups mean groups in particular with a chain length n of 1≤n≤100, preferably 1≤n≤50, further preferred 1≤n≤20, especially preferred 1≤n≤10. Further preferred chain lengths are, for example, chain lengths in the range of 2≤n≤20 and 2≤n≤10 and 3≤n≤20 and 3≤n≤10.

Even short alkyl groups, short at least partially fluorinated alkyl groups or short perfluorinated alkyl groups can achieve the desired effect of reducing adhesion. The shorter the alkyl groups, the thinner the forming layer and the less the desired properties of the radiation entrance surface or the radiation exit surface are influenced. Furthermore, the chain length of the alkyl groups, at least partially fluorinated or perfluorinated alkyl groups, may be greater than or equal to 2, in particular greater than or equal to 3 so that the adhesion-reducing effect can be fully effective.

By using head groups comprising fluorinated alkyl groups, the adhesion of or wettability with encapsulation material can be significantly reduced. The higher the degree of fluorination of the alkyl group, the more strongly the adhesion can be reduced. This effect is particularly pronounced with perfluorinated alkyl groups of the general formula CₙF₂ₙ₊₁.

For example, the head group may be non-fluorinated, at least partially fluorinated or perfluorinated methyl, ethyl, n-propyl, n-butyl, n-pentyl, n-hexyl, n-heptyl, n-octyl, n-nonyl, n-decyl.

The anchor group of the chemical compounds may be bound to the inorganic material by at least one covalent bond, at least one coordinate bond or at least one covalent bond and at least one coordinate bond. It is therefore a directional bond in which the chemical compounds are bound to the radiation exit or entrance surface by chemi sorption, resulting in a particularly stable bond. The reduction of wettability or the tendency of encapsulation material to adhere is thus based on a controlled surface coating of the radiation exit or entrance surface by covalently bonding chemical compounds to change the surface character and in particular to reduce the surface energy.

The anchor group of the chemical compounds may be bound by a covalent and/or coordinative bond to chemically active centers at the radiation exit or entrance surface. The chemically active centers may be functional groups at the radiation exit or entrance surface which, due to their chemical nature, are suitable for forming covalent bonds, coordinative bonds or covalent and coordinative bonds with the anchor groups of the chemical compounds. The design of the chemically active centers can be influenced by various types of pre-treatment of the inorganic material. Depending on the ground and material combination, different plasma treatments are possible, for example, under low pressure or atmospheric conditions, using different types of gases or gas mixtures. Wet chemical pretreatments or pretreatment with UV radiation are also possible. In principle, however, it is also possible to use the inorganic material without pretreatment.

In principle, all functional groups at the radiation exit or entrance surface are possible as chemically active centers that can be linked as partners with a suitable anchor group. Examples can be radicals or metastable hydroperoxides. The anchor group can still be an electrophile, and the active chemical center on the radiation exit or entrance surface can be a nucleophile and vice versa.

A high affinity of the anchor groups of the chemical compound to the active centers or the inorganic material of the radiation exit or entrance surface can be ensured by suitable selection of the active centers or the inorganic material of the radiation exit or entrance surface. This means that the chemical compounds organize themselves especially within the protective layer. The chemical compounds thus spontaneously form a high-order layer, in particular an SAM. The radiation exit or entrance surface thus serves as the seed layer for alignment of the chemical compound. The self-organization process in formation of an SAM has, in particular, a self-terminating character. In other words, the layer structure and thus the further accumulation of the chemical compound is automatically interrupted after occupation of the active centers and/or formation of a monolayer of the chemical compounds.

Typical active chemical centers on the radiation exit or entrance surface may be OH, OOH, R^{C}—COOH, NY₂ groups bonded to the radiation exit or entrance surface. R^{C} stands for a hydrocarbon residue, for example, a methylene residue. Y within the NY₂ group stands for Y═H or Alykl (for example, methyl, ethyl and the like) and can be produced by pretreatment with an NH₃ plasma (or similar plasmas). In particular, chemically active centers in the form of NH₂ groups can be formed by pretreatment with NH₃ plasma.

The anchor group of the chemical compound may be a phosphonic acid, sulfonic acid, carboxylic acid, thiol, hydroxy or silane group, preferably a phosphonic acid, thiol or silane group, especially preferred a phosphonic acid group. A combination of a phosphonic acid anchor group with a radiation exit surface or radiation entrance surface comprising a metal oxide or a combination of a silane anchor group having a radiation exit surface or radiation entrance surface comprising a glass has proven to be particularly advantageous in terms of bonding chemical compounds to the radiation exit surface or radiation entrance surface.

With these anchor groups, in particular with a phosphonic acid group, a particularly strong binding of the chemical compound to a metal oxide or a metal of the metal oxide or to the radiation exit or entrance surface is possible. In particular, the phosphonic acid group has a particularly high affinity for the oxygen of a metal oxide as an inorganic material and for hydroxyl groups so that the chemical compounds with a phosphonic acid group as an anchor group are automatically aligned on the radiation exit or radiation entrance surface such that the anchor groups are located on the radiation exit or radiation entrance surface, while the head groups are directed outwards, for example, away from the radiation exit or radiation entrance surface. In particular, a monomolecular layer or a self-organizing monomolecular layer of chemical compounds forms a protective layer. Further deposition of the chemical compounds above the monomolecular layer is achieved by repulsion of the anchor and head groups.

In addition to the anchor group and the head group, the chemical compounds may also have a middle group arranged between the anchor group and the head group. For example, the middle group can be covalently bound directly to the anchor group on the one hand and to the head group on the other hand.

By selecting suitable middle groups, particularly densely packed and ordered layers can be achieved. For example, particularly compact self-organizing monolayers can be achieved in this way.

In addition, we found that it is possible, for example, to use a highly fluorinated alkyl residue (for example, an alkyl residue in which more than 50% of the H atoms are replaced by F atoms, preferably more than 75% of the H atoms are replaced by F atoms), in particular a perfluorinated alkyl residue as the head group, whereas it is sufficient for the middle group to use conventional alkyl residues without fluorination or only with partial fluorination. However, it is also possible that the middle group may also contain perfluorinated alkyl residues.

The middle group may be selected from a group comprising linear alkyls and linear fluorinated alkyls. The middle group preferably has 1 to 100 carbon atoms in its backbone of the middle group, especially 1 to 50, further preferably 1 to 20, especially preferably 1 to 10 and most preferably 1 to 5 carbon atoms. For example, the middle group may have the general formula —(CH₂)ₙ— (with n=1 to 100, in particular n=1 to 50, preferably n=1 to 20, more preferably n=1 to 10, most preferably n=1 to 5). The middle group prefers linear alkyls, i.e., a non-fluorinated hydrocarbon chain. In addition to the covalent bonding of the chemical compound by the anchor group to the radiation exit or entrance surface, a lateral stabilization of the protective layer by non-covalent interaction such as Van-der-Waals interactions between adjacent chemical compounds occurs.

The anchor group may have one of the following formulas:

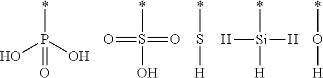

wherein * stands for the connection of the anchor group to the middle group or head group. Anchor groups with OH, SiH or SH groups have proven to be particularly advantageous, as they enable a particularly strong bond to the inorganic material of the radiation exit or entrance surface, in particular to a metal oxide. In addition, these groups have a high affinity to active centers such as OH groups so that a monomolecular layer or a self-organizing monolayer can be formed as a protective layer.

Preferably, the anchor group is a phosphonic acid group. Via the three oxygen atoms of the phosphonic acid group, a particularly strong bond to the inorganic material, preferably the metal oxide, is possible since the bond can be made via one, two or preferably three oxygen atoms. The connection can be made via covalent, coordinative or covalent and coordinative bonds.

The chemical compound may be selected from the following phosphonic acids:

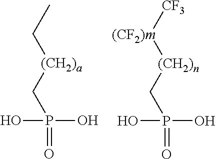

wherein a is an integer with a=0-30, preferably a=0-25, especially preferred a=0-15; m and n is an integer with n=0-20, preferably n=0-10, especially preferred n=0-5 and m=0-20, preferably m=0-10, especially preferred m=0-5. The longer the non-fluorinated alkyl chain, the more densely packed the chemical compounds can be due to Van-der-Waals bonds. The chemical compound of one of the following phosphonic acids is particularly preferred:

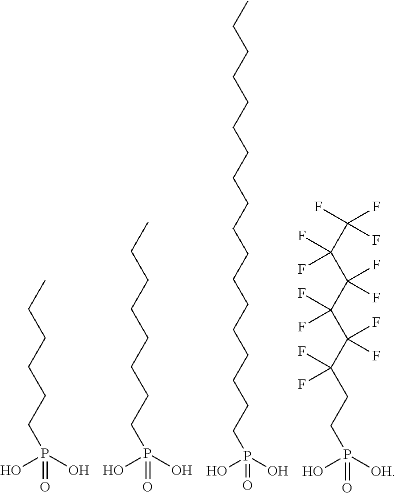

These compounds have proven to be particularly effective with regard to the adhesion-reducing properties for encapsulation materials due to the head groups on the one hand and on the other hand with regard to the fixed connection to the radiation entrance or radiation exit surface via the phosphonic acid anchor groups.

The active layer stack may be arranged on a substrate, and the radiation entrance or radiation exit surface corresponds to a main surface of the active layer stack facing away from the substrate. In particular, the active layer stack can be a radiation-emitting semiconductor chip and the device can thus be designed as a light-emitting or laser diode.

An optical element may be arranged above the active layer stack and the radiation entrance or radiation exit surface is a main surface of the optical element facing away from the active layer stack. The optical element can be, for example, a light scattering platelet or a conversion element.

The optical element can be attached or fixed to the active layer stack by an adhesive. In particular, the adhesive may be a silicone-based adhesive.

The active layer stack may be a radiation emitting semiconductor chip and the optical element may be a conversion element that converts the radiation emitted by the semiconductor chip. The radiation entrance or radiation exit surface corresponds to a main surface of the conversion element facing away from the semiconductor chip. The conversion element comprises an inorganic material, in particular a metal oxide, metal fluoride, metal oxynitride or metal nitride. It can be a metal oxide formed as a phosphor such as Y₃Al₅O₁₂:Ce, for example. Further examples of phosphors are (Ca,Sr)AlSiN₃:Eu²⁺, (La,Ca)₃Si₆(N,O)₁₁:Ce³⁺ and (K,Na)₂(Si,Ti)F₆:Mn⁴⁺.

However, the conversion element may also comprise or consist of the inorganic material and a phosphor. Fluorescent materials for the conversion of radiation are known.

The optoelectronic device may comprise an encapsulation laterally surrounding at least the active layer stack, the active layer stack and the protective layer, the active layer stack and the optical element, the active layer stack and the optical element and the protective layer. Due to the reduced wettability of the protective layer, no or only little encapsulation material is deposited on it. Any deposited encapsulation material still adheres poorly to the protective layer so that it can be removed very easily if necessary. This has the advantage that the optical properties such as brightness and radiation characteristics of the device are not impaired. The encapsulation comprises or consists, for example, of a silicone, epoxy resin or hybrid materials, for example, inorganic-organic hybrid materials. The encapsulation material may contain fillers such as inorganic filler particles or fibers, in particular silicon dioxide, glass and/or titanium dioxide.

The encapsulation protects the active layer stack or the active layer stack and the optical element from external damaging influences, for example, mechanical stress. The encapsulation can be especially reflective for the radiation converted from the active layer stack and optionally for the radiation converted from the conversion element (for example, when the device is a light-emitting diode or laser diode) or for the radiation received from the surroundings by the device (for example, when the device is a light detector).

The radiation entrance or radiation exit surface and preferably also the protective layer may be flat. In other words, the radiation entrance or radiation exit surface and preferably also the protective layer is flat within the producing tolerance and has no or hardly any elevations or depressions. In particular, a subsequent injection molding process for lateral overmolding of at least the active layer stack can thus be easily carried out.

The optoelectronic device may be a light-emitting diode, laser diode or light detector.

The optoelectronic device may be produced according to the following process. All the characteristics of the optoelectronic device shall also apply to the process of producing an optoelectronic device and vice versa.

Our process of producing an optoelectronic device includes the steps:

A) providing an active layer stack that generates or detects radiation on a substrate,
B) applying chemical compounds, each containing an anchor group and a head group, to a surface of the optoelectronic device provided as a radiation entrance or radiation exit surface, the surface comprising an inorganic material,
C) reacting the anchor group of the chemical compounds with the inorganic material of the radiation entrance or radiation exit surface to form a protective layer,
D) arranging an encapsulation material to form an encapsulation laterally surrounding at least the active layer stack or at least the active layer stack and the protective layer.

Due to the reaction of the anchor groups of the chemical compounds with the inorganic material, the anchor groups are bound to the inorganic material in particular via covalent and/or coordinative bonds. This creates a strong binding between the protective layer and the radiation entrance or radiation exit surface. The advantage is that the protective layer can no longer be removed without effort from the radiation entrance or radiation exit surface. The protective layer reduces the adhesion tendency or wetting tendency compared to the encapsulation material used in step D) on the surface of the protective layer opposite the radiation entrance or radiation exit surface compared to the radiation entrance or radiation exit surface without the protective layer. This is achieved by selecting the appropriate head groups of the chemical compound.

In step D) the encapsulation material may be arranged to form an encapsulation laterally surrounding the active layer stack and the optical element or the active layer stack, the optical element and the protective layer.

In step D), for example, the active layer stack, the active layer stack and the protective layer, the active layer stack and the optical element arranged thereon, or the active layer stack and the optical element arranged thereon and the protective layer can be encapsulated with an encapsulation material, in particular by injection molding such as film assisted molding. “Film assisted molding” is known. Due to the reduced adhesion and wetting properties of the protective layer for the encapsulation material, the adhesion of the encapsulation material is reduced and any resulting deposit of the encapsulation material can be removed more easily. This means that overflow and accumulation of encapsulation material on the protective layer can be prevented. Thus, the optical properties of the surface intended as the radiation entrance or radiation exit surface are retained after sealing. A possibly nevertheless developing flash can be removed very easily by poorer adhesion at the surface.

The surface of the optoelectronic device intended as the radiation entrance or radiation exit surface may be a main surface of the active layer stack facing away from the substrate.

The surface of the optoelectronic device intended as the radiation entrance or radiation exit surface may be a main surface of an optical element. In particular, the optical element is arranged above the active layer stack. The optical element is preferably placed on the active layer stack after formation of the protective layer and thus after step C). The optical element can be a light scattering platelet or a conversion element.

The surface of the optoelectronic device intended as the radiation entrance or radiation exit surface may be subjected to a pretreatment prior to process step B). Pretreatment refers to a surface treatment or surface functionalization. The type of pretreatment must be adapted to the type of ground, i.e., the properties of the inorganic material, and to the nature of the anchor group of the chemical compound. Examples of pretreatments can be UV radiation or plasma treatment.

We found that the density of the chemically active centers can be significantly increased by pretreating the surface intended as the entrance or exit surface for radiation. UV radiation and/or plasma treatment can break chemical bonds on the surface of the inorganic material to form highly reactive or metastable groups such as radicals, hydroxides or hydroperoxides. They increase the reactivity of the inorganic material and can either react themselves with the anchor group of the chemical compounds or further react to functional groups on the surface intended as the radiation entrance or radiation exit surface (for example, hydroxy groups). In this way, more functional groups are available on the surface intended as the radiation entrance or radiation exit surface for a reaction with the anchor groups of the chemical compounds. In this way, a higher density of chemical compounds can be achieved as a surface intended for radiation entrance or radiation exit, a more compact layer can be produced and this can be further reduced.

The pre-treatment can be carried out with a plasma. Particularly suitable plasmas are, for example, oxygen plasma, argon plasma and NH₃ plasma or plasma from mixtures of these gases. But other common plasma treatments can also be used. For large-area or industrial applications, the use of atmospheric plasma with air as a process gas is also suitable, provided that there are no oxidation-sensitive surfaces.

We also found that the use of an oxygen plasma can significantly increase the density of the chemically active centers on the surface intended as the radiation entrance or radiation exit surface, in particular OH and OOH groups, but also R^{C}—COOH groups (wherein R^{C} is an alkyl group, for example, methylene). In this way, significantly more chemical compounds can be bonded to the surface intended as the radiation entrance or radiation exit surface, which leads to a greater reduction in adhesion.

NH₃ plasmas can be used to generate nitrogen-containing surface centers such as the aforementioned NY₂ centers.

We further found that the density of the active chemical surface centers on the surface intended as the entrance or exit surface for radiation can be increased even without oxidizing plasmas. Suitable are, for example, plasmas of hydrogen or mixtures of hydrogen and argon. Inert gas plasmas can also be used. Especially plasmas of noble gases like argon plasma or helium plasma are suitable.

According to a further example of the process, process step B) is carried out with a process selected from a group comprising dip coating, spray coating, spin coating, vapor deposition, in particular chemical vapor deposition (CVD). The use of plasma enhanced chemical vapor deposition (PECVD) is also possible.

The reaction of the anchor group with the radiation entrance or radiation exit surface as part of a dip, spin or spray coating can lead to reliable layer formation and thus a reduction in adhesion. At the same time, these processes are suitable for use on an industrial scale. Dip, spin and spray coatings are particularly suitable for chemical compounds that are difficult to evaporate.

The separation from the gas phase is suitable for the separation into the gas phase without decomposition of transferable chemical compounds and is particularly suitable for the industrial scale. It allows the protective layer to be produced quickly and cost-effectively.

The process may comprise a process step E): E) removing the protective layer. Process step E) is carried out in particular after process step D). The protective layer can be removed by plasma cleaning, for example.

Further advantages and developments result from the examples described in the following in connection with the figures.

In the examples and figures, identical, similar or equivalent elements can each be provided with the same reference numerals. The illustrated elements and their proportions among each other are not to be regarded as true to scale. Rather, individual elements such as layers, devices, building elements and areas, may be oversized for better representability and/or better understanding.

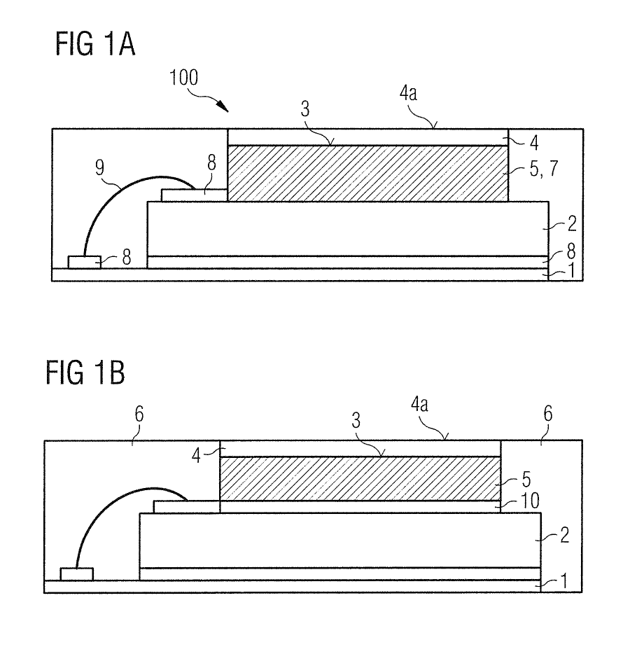

FIG. 1A shows an optoelectronic device 100 in the form of a light-emitting diode. An active layer stack 2 is arranged on a substrate 1 to generate electromagnetic radiation, for example, by thin-film soldering. The solder or connection layer is not shown. An optical element 5 is arranged above the active layer stack 2 as a conversion element 7. The conversion element 7, for example, contains converter particles adapted to at least partially convert the radiation generated by the active layer stack 2 into electromagnetic radiation in a longer wavelength region and a metal oxide, and is formed as a ceramic platelet. The radiation generated by the active layer stack 2 and converted by the conversion element 7 (in a partial conversion) or the radiation converted by the conversion element (in a full conversion) is decoupled to the surroundings via the radiation exit surface 3 and usually forms an interface between the device and the surroundings. A protective layer 4 is arranged above the radiation exit surface 3. The protective layer 4 is a self-organizing monomolecular layer consisting of chemical compounds each containing an anchor group and a head group. The anchor group is bound to the metal oxide of the optical element 5 via covalent or covalent and coordinative bonds. The head group of the chemical compounds ensures that the surface of the protective layer 4a facing away from the radiation exit surface has a low affinity for the adhesion of dirt and dust particles as well as an encapsulation material 14. The metallizations 8 and the bonding wire 9 are used for electrical contacting of the device 100. The device 100 has an encapsulation 6. The encapsulation 6 comprises or consists of an encapsulation material 14, for example, a silicone. The substrate 1, the active layer stack 2, the optical element 5 and the protective layer 4 are laterally enclosed by the encapsulation 6. Due to the chemical compounds present in the protective layer 4, in particular their head groups, the surface of the protective layer 4a exhibits a reduced adhesion of the encapsulation material 14 and/or a reduced wettability for the encapsulation material. As a result, when the encapsulation material 14 is applied, for example, by injection molding, it does not or hardly deposit on the surface 4a or can be removed from it very easily.

Compared to the optoelectronic device 100 shown in FIG. 1A, the optoelectronic device 100 of FIG. 1B has an adhesive layer 10 over which the optical element 5 is fixed on the active layer stack 2. The adhesive layer 10 contains in particular a silicone or is based on a polysiloxane.

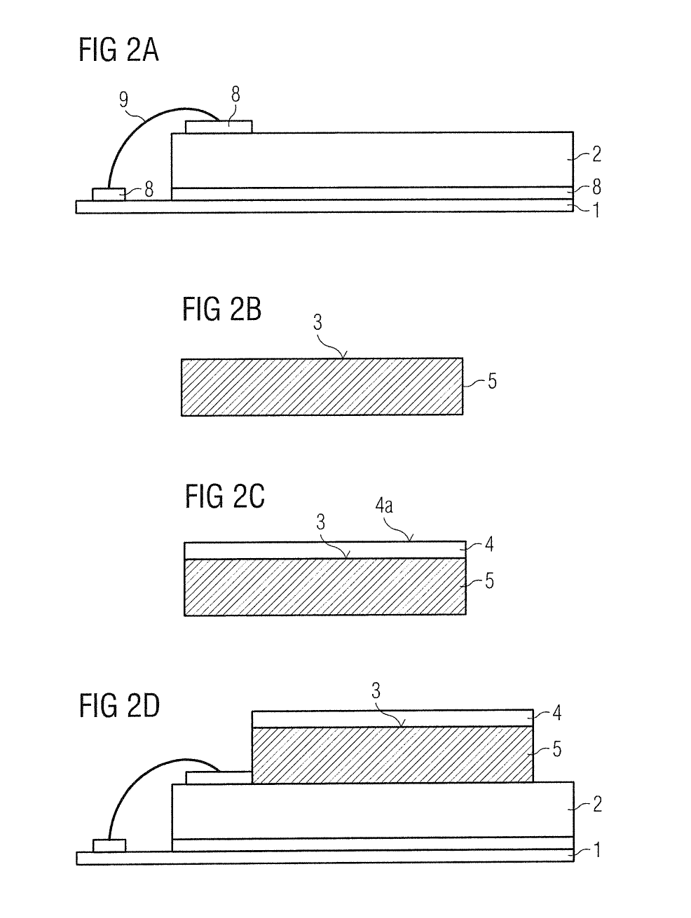

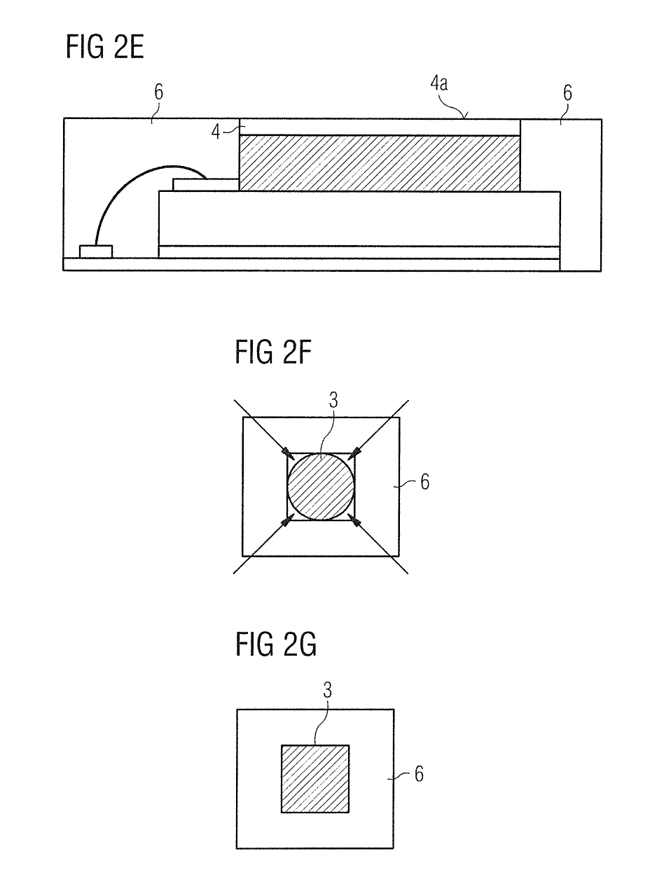

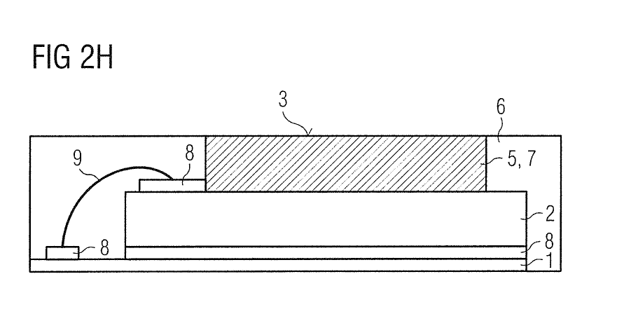

FIG. 2 shows a process of producing an optoelectronic device. According to FIG. 2A, an active layer stack 2 is provided to generate electromagnetic radiation. The active layer stack 2 is arranged on a substrate 1 and electrically contacted via metallizations 8 and a bonding wire 9.

Further, an optical element 5 is provided (FIG. 2B). The optical element 5 can be a conversion element or a light scattering platelet. The optical element 5 comprises or consists of a metal oxide, for example, an SiO₂ glass. Optionally, the optical element 5 can be pretreated with a plasma (not shown). For example, by using an oxygen plasma, OH groups can be formed as chemically active centers on the surface 3 intended as the radiation entrance or radiation exit surface.

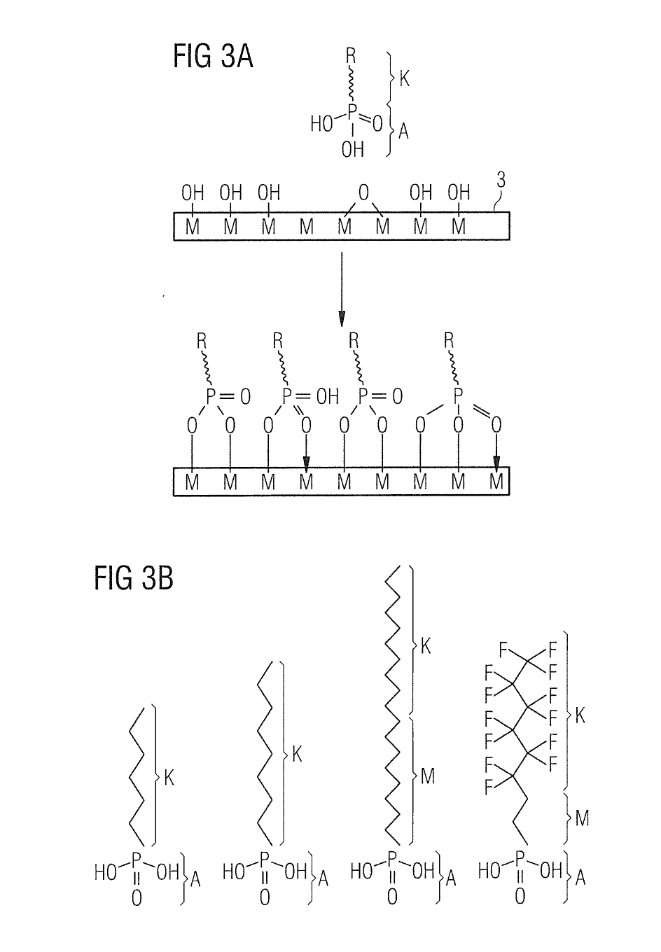

Chemical compounds are applied to the surface of the optical element intended as the radiation entrance or radiation exit surface 3 by spray coating, for example. In particular, the chemical compound is one of the phosphonic acids shown in FIG. 3B. The phosphonic acid group serves as an anchor group for the chemical bonding of the chemical compound via covalent or covalent and coordinative bonds to the metal oxide of the surface of the optical element 5 intended as the radiation entrance or radiation exit surface 3. The phosphonic acid groups of the chemical compounds have a high affinity for the active centers or the metal oxide of the surface of the optical element 5 intended as the radiation exit or radiation entrance surface 3. As a result, the chemical compounds organize themselves within the forming protective layer 4. In particular, the chemical compounds spontaneously form a high-order layer, especially an SAM. The surface provided as the radiation exit or radiation entrance surface 3 thus serves as the seed layer for the alignment of the chemical compound. The self-organization process in the forming of an SAM has a self-determining character. In other words, the layer structure and thus the further accumulation of chemical compounds is automatically interrupted after the formation of the monolayer. The chemical compounds are arranged within the protective layer 4 such that the head groups, here alkyl or fluorinated alkyl groups, face outwardly and are thus arranged on the surface of the protective layer 4a opposite the radiation exit or radiation entrance surface 3 (FIG. 2C).

The optical element 5 with the protective layer 4 is arranged on the active layer stack 2. The protective layer 4 is located on a side of the optical element 5 facing away from the active layer stack 2 (FIG. 2D). The optical element 5 can be fixed on the active layer stack 2 via an adhesive layer 10 (not shown).

An encapsulation 6 that laterally encloses the substrate 1, the active layer stack 2, the optical element 5 and the protective layer 4 is arranged by an injection molding process, in particular by “film assisted molding” (FIG. 2E). The chemical compounds present in the protective layer 4 have fluorinated or non-fluorinated alkyl groups as their head groups, which are directed outwardly within protective layer 4 and are thus located on a surface of the protective layer 4a facing away from the radiation exit surface. As a result, the surface 4a has a low affinity for the adhesion of the encapsulation material 14, or deposited encapsulation material 14 can be very easily removed from the surface 4a. This ensures that the optical properties of the device are not affected by deposited and/or adhering encapsulation material 14.

FIG. 2F shows a plan view of the device 100 directly after the injection molding process. Encapsulation material 14 is deposited on the side surfaces of the radiation exit surface 3 marked with arrows. This can be easily cleaned away. FIG. 2G shows the top view of the finished device 100 after cleaning the radiation exit surface from the encapsulation material 14. The side view of the finished device is shown in FIG. 1B.

Optionally, the protective layer 4 can at least partially, preferably completely be removed in a further process step, for example, by plasma cleaning. According to FIG. 2H, this step is shown after an arrangement of encapsulation 6. The radiation exit surface of the optical element 3 facing away from the active layer stack 2 is therefore no longer covered by the protective layer 4.

FIG. 3A shows a surface of an optical element 5 or an active layer stack 2 intended as a radiation exit surface or radiation entrance surface 3. A metal oxide is arranged on the surface provided as the radiation exit surface or radiation entrance surface 3. OH groups or metal oxide bonds are present as active centers on the surface intended as the radiation exit surface or radiation entrance surface 3. A chemical compound with a head group K and an anchor group A attaches itself to the surface provided as the radiation exit surface or radiation entrance surface 3, forming covalent and coordinative bonds, in particular metal-oxygen bonds. Due to the high affinity of the anchor group to the metal oxide and/or the active centers, the chemical compound aligns itself and a highly ordered protective layer 4 is formed, in particular an SAM. FIG. 3B shows examples of chemical compounds having a head group K and anchor group A or a head group K, a middle group M and an anchor group A.

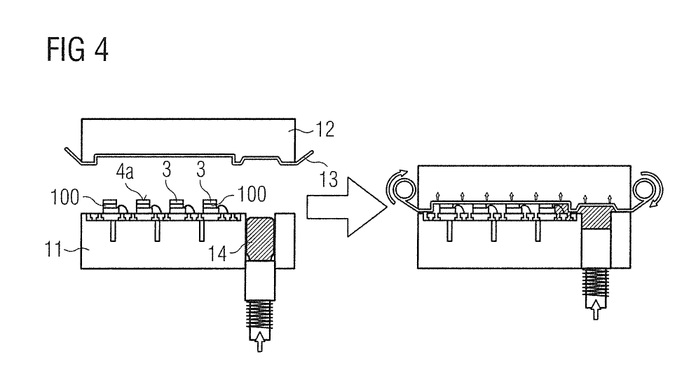

FIG. 4 shows a “film assisted molding” process of arranging an encapsulation 6. The process is known and explained here only briefly. A large number of optoelectronic devices 100 are arranged in a first mold 11. A second mold 12 is equipped with a separating foil 13 sucked in by a vacuum. The second mold 12 is arranged on the first mold 11. The encapsulation material 14 is heated and pressed into the spaces between the first mold 11 and the second mold 12. Due to the vacuum applied to suck in the separating foil 13 in the second mold 12, the encapsulation material is usually also partially arranged on the radiation exit surface 3 if the height tolerances of the chip compound are too high. Due to the arrangement of the protective layer 4 on the radiation exit surface 3, the surface 4a has a low affinity for the adhesion of the encapsulation material and deposited encapsulation material can easily be removed from this surface 4a.

Our devices and methods are not limited by the description of the examples. Rather, this disclosure includes any new feature and any combination of features, which in particular includes any combination of features in the appended claims, even if the feature or combination itself is not explicitly mentioned in the claims or examples.

This application claims priority of DE 10 2017 130 528.9, the subject matter of which is incorporated herein by reference.

1. An optoelectronic device comprising:
an active layer stack that generates or detects radiation,
a radiation entrance or radiation exit surface comprising an inorganic material, and
a protective layer disposed over the radiation entrance or radiation exit surface and comprising chemical compounds each containing an anchor group and a head group, wherein the anchor group is bonded to the inorganic material, and
an encapsulation laterally surrounding at least the active layer stack or at least the active layer stack and the protective layer.

2. The optoelectronic device according to claim 1, wherein the inorganic material is at least one selected from the group consisting of an oxide, a nitride, an oxynitride, a carbide, a carbonitride, a fluoride and a silicate.

3. The optoelectronic device according to claim 1, wherein the inorganic material is a glass, ceramic or sapphire.

4. The optoelectronic device according to claim 1, wherein the protective layer is a monomolecular layer consisting of the chemical compounds each containing an anchor group and a head group.

5. The optoelectronic device according to claim 1, wherein the protective layer is a self-organizing monomolecular layer consisting of the chemical compounds each containing an anchor group and a head group.

6. The optoelectronic device according to claim 1, wherein the head group is selected from the group consisting of linear alkyl groups, branched alkyl groups, at least partially fluorinated linear alkyl groups, at least partially fluorinated branched alkyl groups, perfluorinated linear alkyl groups and perfluorinated branched alkyl groups.

7. The optoelectronic device according to claim 1, wherein the anchor group is selected from the group consisting of a phosphonic acid, sulfonic acid, carboxylic acid, thiol, hydroxy and silane group.

8. The optoelectronic device according to claim 1, wherein the anchor group is bonded to the inorganic material by covalent, coordinate, or covalent and coordinate bonds.

9. The optoelectronic device according to claim 1, wherein the active layer stack is arranged on a substrate and the radiation entrance or radiation exit surface corresponds to a main surface of the active layer stack facing away from the substrate.

10. The optoelectronic device according to claim 1, wherein an optical element is arranged above the active layer stack and the radiation entrance or radiation exit surface corresponds to a main surface of the optical element facing away from the active layer stack.

11. The optoelectronic device according to claim 10, wherein the encapsulation laterally surrounds the optical element.

12. The optoelectronic device according to claim 11, wherein the active layer stack is a radiation-emitting semiconductor chip and the optical element is a conversion element that converts the radiation emitted by the semiconductor chip, and the radiation entrance or radiation exit surface corresponds to a main surface of the conversion element facing away from the semiconductor chip.

13. A process of producing the optoelectronic device according to claim 1 comprising:
A) providing the active layer stack that generates or detects radiation on the substrate,
B) applying the chemical compounds, each containing an anchor group and a head group, to the surface of the optoelectronic device provided as the radiation entrance or radiation exit surface, said surface comprising the inorganic material,
C) reacting the anchor group of the chemical compounds with the inorganic material of the radiation entrance or radiation exit surface to form the protective layer,
D) arranging the encapsulation material to form the encapsulation laterally surrounding at least the active layer stack or at least the active layer stack and the protective layer.

14. The process according to claim 13, wherein the surface of the optoelectronic device provided as the radiation entrance or radiation exit surface corresponds to a main surface of the active layer stack facing away from the substrate.

15. The process according to claim 13, wherein Al) the surface of the optoelectronic device provided as the radiation entrance or radiation exit surface corresponds to a main surface of an optical element.

16. The process according to claim 13, wherein a surface of the optoelectronic device provided as a radiation entrance or radiation exit surface is treated with UV radiation or a plasma prior to step B).

17. An optoelectronic device comprising:
an active layer stack that generates or detects radiation,
a radiation entrance or radiation exit surface comprising an inorganic material,
a protective layer disposed over the radiation entrance or radiation exit surface and comprising chemical compounds each containing an anchor group and a head group, wherein the anchor group is bonded to the inorganic material, and
an encapsulation laterally surrounds at least the active layer stack or the at least the active layer stack and the protective layer,
wherein
the inorganic material is at least one selected from the group consisting of an oxide, a nitride, an oxynitride, a carbide, a carbonitride, a fluoride and a silicate without silicone.
